(19) United States
(12) Patent Application Publication
(10) Pub. No.: US 2011/0163340 A1
(43) Pub. Date: Jul. 7, 2011

(54) Organic Electroluminescent Device

(75) Inventor: Euan C. Smith, Cambridgeshire (GB)

(73) Assignee: CAMBRIDGE DISPLAY TECHNOLOGY LIMITED

(21) Appl. No.: 12/995,658

(22) PCT Filed: Jun. 2, 2009
(86) PCT No.: PCT/GB09/01371

§ 371 Date: Mar. 14, 2011

(30) Foreign Application Priority Data
Jun. 3, 2008 (GB) 0810115.6

(51) Int. Cl. H01L 51/52; H01L 51/56

(52) U.S. Cl. 257/98; 438/27; 257/E51.018

(57) ABSTRACT

An organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode, the second electrode being transparent to light emitted by the light emitting layer; a glass or transparent plastic encapsulant disposed over, and spaced apart from, the second electrode, defining a cavity therebetween; and a cavity filling material disposed within the cavity, the cavity filling material extending from a bottom side of the cavity to a top side of the cavity, the cavity filling material having an optical structure disposed therein.

### FIELD OF THE INVENTION

The present invention relates to an organic electroluminescent device and a method of manufacture thereof.

### BACKGROUND OF THE INVENTION

Organic electroluminescent devices are known, for example, from PCT/WO/13148 and U.S. Pat. No. 4,539,507. Examples of such devices are shown in FIGS. 1 and 2. Such devices generally comprise: a substrate 2; a first electrode 4 disposed over the substrate 2 for injecting charge of a first polarity; a second electrode 6 disposed over the first electrode 4 for injecting charge of a second polarity opposite to said first polarity; an organic light emitting layer 8 disposed between the first and the second electrodes; and an encapsulant 10 disposed over the second electrode 6. In one arrangement shown in FIG. 1, the substrate 2 and first electrode 4 are transparent to allow light emitted by the organic light-emitting layer 8 to pass therethrough. In another arrangement shown in FIG. 2, the second electrode 6 and the encapsulant 10 are transparent so as to allow light emitted from the organic light-emitting layer 8 to pass therethrough.

Variations of the above described structures are known. The first electrode may be the anode and the second electrode may be the cathode. Alternatively, the first electrode may be the cathode and the second electrode may be the anode. Further layers may be provided between the electrodes and the organic light-emitting layer in order to aid charge injection and transport. The organic material in the light-emitting layer may comprise a small molecule, a dendrimer or a polymer and may comprise phosphorescent moieties and/or fluorescent moieties. The light-emitting layer may comprise a blend of materials including light emitting moieties, electron transport moieties and hole transport moieties. These may be provided in a single molecule or in separate molecules.

By providing an array of devices of the type described above, a display may be formed comprising a plurality of emitting pixels. The pixels may be of the same type to form a monochrome display or they may be different colours to form a multicolour display.

A problem with organic electroluminescent devices is that much of the light emitted by organic light-emitting material in the organic light-emitting layer does not escape from the device. The light may be lost within the device by scattering, internal reflection, wave guiding, absorption and the like. For example, it will be understood that light is emitted from the electroluminescent layer over a range of angles relative to the plane of the device. Light hitting an interface in the device at a shallow angle can be internally reflected.

One way of increasing the amount of light which escapes from the device is to provide an optical structure in the device which reduces one or more of scattering, internal reflection, wave guiding, absorption and the like. Such an optical structure may, for example, comprise a diffraction grating or a microlens array.

An earlier application of the present applicant, published as GB2421626, discloses forming an optical structure in a thin film encapsulant of an organic electroluminescent device by depositing the layers of the electroluminescent device, depositing a thin layer encapsulant over the device layers, and providing an optical structure in the encapsulant by, for example, embossing an optical structure therein. Such an arrangement provides a so called top-emitting device structure with an optical structure to increase light output from a top side of the device. Such an arrangement is illustrated in FIG. 3 comprising: a substrate 2; a first electrode 4 disposed over the substrate 2 for injecting charge of a first polarity; a second electrode 6 disposed over the first electrode 4 for injecting charge of a second polarity opposite to the first polarity; an organic light emitting layer 8 disposed between the first and the second electrode; and a thin film encapsulant 10 disposed over the second electrode 6, wherein the second electrode 6 is transparent to light emitted by the light emitting layer 8 and an optical structure 12 is provided in the thin film encapsulant 10.

One possible problem with the aforementioned arrangement is that forming an optical structure in the thin film encapsulant by, for example, embossing can damage underlying layers of the device.

As an alternative, or in addition to, a thin film encapsulant disposed over the top electrode of an organic electroluminescent device, a layer of glass or transparent plastic may be provided over the device to encapsulate the device against moisture and oxygen ingress. The layer of glass or transparent plastic usually has a recess formed therein to receive the device and provide a seal around the periphery of the device. The recess is generally deep enough to space the glass or transparent plastic encapsulant from the upper surface of the device in order to prevent the upper surface of the top electrode being damaged during encapsulation. A cavity is thus formed between the upper surface of the top electrode and the glass/plastic encapsulant. Such an arrangement is illustrated in FIG. 4 comprising: a substrate 2; a first electrode 4 disposed over the substrate 2 for injecting charge of a first polarity; a second electrode 6 disposed over the first electrode 4 for injecting charge of a second polarity opposite to the first polarity; and an organic light emitting layer 8 disposed between the first and the second electrode. A thin film encapsulant (not shown) may be optionally disposed over the second electrode 6. A glass or transparent plastic encapsulant 14 having a recess formed therein is disposed over the aforementioned layers and bonded to the substrate 2 with an adhesive 16 around the periphery of the organic electroluminescent device. The glass or transparent plastic encapsulant 14 is spaced from the upper surface of the top electrode 6 forming a cavity 18.

One problem with the arrangement shown in FIG. 4 is that due to the differences in refractive index at the interfaces between the top electrode and the cavity, the cavity and the encapsulant, and the encapsulant and the overlying air, a large amount of light is lost through internal reflection.

It is an aim of the present invention is to address one or more of the aforementioned problems.

### SUMMARY OF THE INVENTION

One possibility to address the problem of reduced light output caused by the cavity in the arrangement of FIG. 4 would be to merely exclude the cavity by forming the recess in the encapsulant to a depth such that the encapsulant sits on top of the upper surface of the organic electroluminescent device layers. However, this has been found to cause damage to the device layers. Unlike a thin film encapsulant, the glass or transparent plastic encapsulant is deposited as a fully formed sheet rather than, for example, a vapour deposited film. As such, the encapsulant is relatively hard and can damage, for example, a top cathode layer if it contacts the layer when it is disposed over the device and bonded to the substrate.

Another possibility would be to fill the cavity with material, such an elastomer, which is softer than the glass or transparent plastic encapsulant. For example, an elastomeric material can be deposited in the recess of the encapsulant prior to the encapsulant being disposed over the organic electroluminescent device. Thus, when the encapsulant is disposed over the organic electroluminescent device, the soft material fills the cavity while providing a buffer between the organic electroluminescent device and the hard encapsulant. The cavity filling material reduces the difference in refractive index at the interface between the top of the device and the cavity, and at the interface between the cavity and the encapsulant. Thus, internal reflection is reduced and light output from the top of the device is increased. The device is also made more robust by the cavity filling material.

While the aforementioned arrangement reduce internal reflection at the interface between the top of the device and the cavity, and at the interface between the cavity and the encapsulant, some internal reflection will still occur at these interfaces unless the refractive index of the cavity filling material exactly matches the material forming the top surface of the organic electroluminescent device and/or the overlying encapsulant. Furthermore, there is still a significant amount of light lost at the interface between the top of the encapsulant and the overlying air.

The present applicant has realized that light loss may be further reduced when compared with the previously discussed arrangements by combining the features of a cavity filling material and an optical structure such that an optical structure is provided in the cavity filling material.

In light of the above, and in accordance with a first aspect of the invention, there is provided an organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode, the second electrode being transparent to light emitted by the light emitting layer; a glass or transparent plastic encapsulant disposed over, and spaced apart from, the second electrode, defining a cavity therebetween; and a cavity filling material disposed within the cavity, the cavity filling material extending from a bottom side of the cavity to a top side of the cavity, the cavity filling material having an optical structure disposed therein.

The optical structure may be one of a corrugated surface, a diffractive structure (e.g. a diffraction grating), a microlens array, a prismatic array, and an array of Fresnel lenses. The optical structure may have a roughened surface to further increase light output from the device.

Preferably, the optical structure is formed in a bottom surface of the cavity filling material. With such an arrangement, the optical structure is formed closer to the organic light emitting layer than, for example, if the optical structure is formed in an upper surface of the cavity filling material adjacent the encapsulant. This is desirable because optical structures can cause undesirable optical side effects. For example, as viewing angle changes undesirable optical effects can be introduced by the presence of the optical structures resulting in, for example, variation in brightness with viewing angle. These optical side effects are dependent on the distance of the optical structure from the light emitting layer. By providing the optical structure close to the light emitting layer, optical side effects are reduced while still increasing light output from a device.

The cavity filling material preferably comprises an elastomer such as PDMS (polymethylsiloxane).

The cavity filling material may comprise a bulk material in which the optical structure is disposed and a coating material. The coating material can be disposed on either or both of top and bottom sides of the bulk material. The coating material may be selected for better refractive index matching at the interfaces located at the top and bottom of the cavity. Alternatively, the coating material coats the optical structure and is selected to increase the difference in refractive index between structural elements of the optical structure to increase the effectiveness of the optical structure. An example of such a coating material is an inorganic material such as SiN. The bulk material may be provided by the previously mentioned elastomer.

Preferably, the glass or transparent plastic encapsulant comprises a recess in which the cavity filling material is disposed. The recess can also receive one or more underlying layers of the device. Most preferably, the glass or transparent plastic encapsulant comprises a recess with side walls disposed around the periphery of the device and bonded to the substrate to form a seal using, for example, a line of adhesive around the periphery of the device. The side walls serve to encapsulate the sides of the device against ingress of moisture and oxygen while also spacing the encapsulant by a suitable distance above the second electrode to prevent damage of the device when the encapsulant is applied.

Preferably the first electrode is an anode and the second electrode is a cathode. The cathode may comprise a layer of barium with a layer of aluminium thereover. Each of these layers is preferably less than 10 nm thick and more preferably each layer is approximately 5 nm thick. This arrangement provides a cathode with good electrical properties while also being transparent. Furthermore, the cathode does not adversely react with other components in the device. An alternative cathode utilizes a layer of barium with a layer of silver thereover. Each of these layers is preferably less than 10 nm thick and more preferably each layer is approximately 5 nm thick. This cathode is more transparent than the aforementioned Barium/Aluminium arrangement.

In one arrangement the substrate, the first electrode and the second electrode are transparent to light emitted by the organic light emitting layer. This arrangement, combined with a transparent encapsulant results in a fully transparent device architecture.

According to a second aspect of the present invention there is provided a method of manufacturing an organic electroluminescent device comprising the steps: depositing a first electrode over a substrate for injecting a charge of a first polarity; depositing an organic light emitting layer over the first electrode; depositing a second electrode over the organic light emitting layer for injecting charge of a second polarity opposite to said first polarity, the second electrode being transparent to light emitted by the light emitting layer; disposing a glass or transparent plastic encapsulant over, and spaced apart from, the second electrode, defining a cavity therebetween, wherein a cavity filling material is provided within the cavity, the cavity filling material extending from a bottom side of the cavity to a top side of the cavity, the cavity filling material having an optical structure disposed therein.

Preferably, the cavity filling material is deposited on the glass or transparent plastic encapsulant prior to disposing the glass or transparent plastic encapsulant over the second electrode. Accordingly, a composite structure is formed comprising the glass or transparent plastic encapsulant and the cavity material which can then be disposed over the organic electroluminescent device structure to encapsulate the organic electroluminescent device.

The optical structure may be formed in the cavity filling material before or after depositing the cavity filling material on the glass or transparent plastic encapsulant. In one preferred embodiment, the cavity filling material is deposited on the glass or transparent plastic encapsulant, the optical structure is formed on an opposite side of the cavity filling material to the glass or transparent plastic encapsulant, and then the resultant composite structure is disposed over the organic electroluminescent device structure to encapsulate the organic electroluminescent device. Such a method allows the optical structure to be formed without damaging active layers of the organic electroluminescent device. However, other possibilities have also been envisaged. For example, the cavity filling material could be deposited over the second electrode, an optical structure formed therein, and then the glass or transparent plastic encapsulant disposed thereover. Alternatively still, the optical structure can be formed in a layer of cavity filling material, the layer of cavity filling material can then been applied over the second electrode, and the glass or transparent plastic encapsulant disposed thereover.

Preferably the optical structure is provided by embossing, printing, etching, photolithographic patterning or the like.

If the optical structure is embossed, the cavity filling material may be softened by heating or the application of a solvent after deposition for embossing the optical structure therein. Alternatively, the cavity filling material may be deposited and an embossing mould applied prior to curing of the cavity filling material. In one preferred method, the cavity filling material is deposited into a recess formed in the encapsulant and an embossing mould is applied to the deposited cavity filling material in the recess to form an optical structure. The cavity filling material is cured by, for example, heating or application of UV light. The embossing mould is then removed and the encapsulant bonded over the organic electroluminescent device.

Preferably, the embossing mould is design to have side walls which abut the side walls of the encapsulant when the embossing mould is applied thereto in order to accurately define the height of the cavity filling material with the optical structure disposed therein.

Alternatively, the optical structure may be embossed using a roller having a patterned surface which may be rolled over the cavity filling material to form the optical structure.

### BRIEF DESCRIPTION OF THE DRAWINGS

Embodiments of the present invention will now be described by way of example only with reference to the accompanying drawings, in which:

FIG. 1 shows a known structure of a bottom-emitting organic light emitting device;

FIG. 2 shows a known structure of a top-emitting organic light emitting device;

FIG. 3 shows a known structure of a top-emitting organic light emitting device with an optical structure in a thin film encapsulant disposed over the device;

FIG. 4 shows a known structure of a top-emitting organic light emitting device with a glass or transparent plastic encapsulant disposed thereover;

FIG. 5 shows a top-emitting organic light emitting device in accordance with an embodiment of the present invention;

FIG. 6 shows a top-emitting organic light emitting device in accordance with another embodiment of the present invention in which the cavity filling material comprises a bulk material and a coating material;

FIG. 7 shows a method of forming a top-emitting organic light emitting device in accordance with an embodiment of the present invention;

FIG. 8 shows the structure of a roller which may be used in accordance with an alternative method of forming a top-emitting organic light emitting device in accordance with an embodiment of the present invention;

FIG. 9 illustrates an example of a fabrication process in accordance with an embodiment of the present invention; and

FIG. 10 shows the steps involved in the imprinting step of FIG. 9.

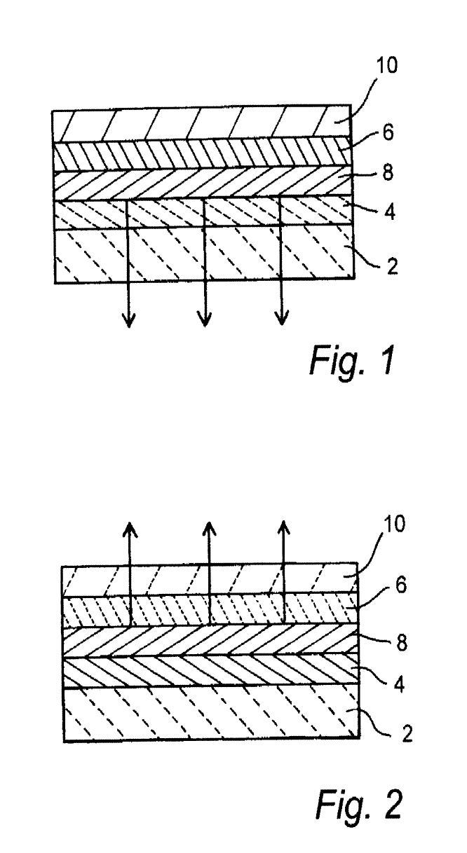

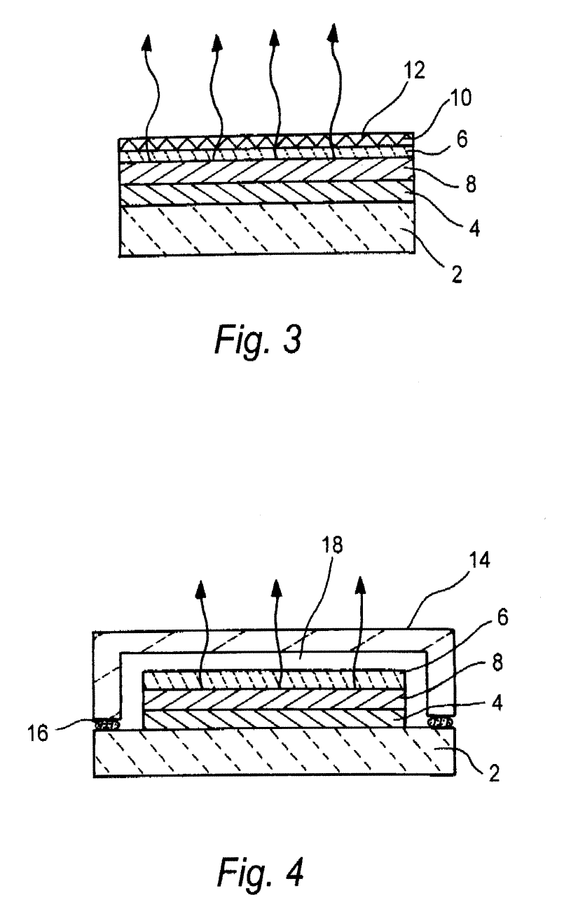

### DETAILED DESCRIPTION OF EMBODIMENTS OF THE PRESENT INVENTION

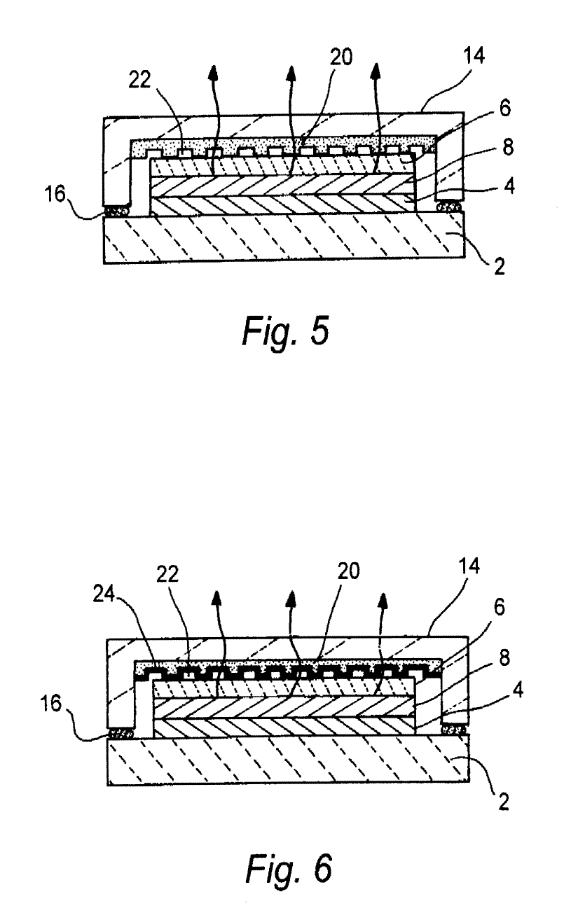

FIG. 5 shows a top-emitting organic light emitting device in accordance with an embodiment of the present invention. The structure of the device is similar in many respects to the prior art arrangement illustrated in FIG. 4 and like reference numerals have been used for like parts. The difference lies in the provision of a cavity filling material 20 disposed between the top electrode 6 and the encapsulant 14 with an optical structure, in this case a diffraction grating, disposed within the cavity filling material 20. The cavity filling material may be an elastomer such as PDMS. The cavity filling material 20 extends from the top electrode 6 to the encapulant 14 thereby substantially filling the cavity disposed therebetween. While the cavity filling material 20 fills, or substantially fills, the cavity disposed between the top electrode and the encapsulant, it will be appreciated that the optical structure may itself comprise voids 22. This can been seen in the diffraction grating illustrated in FIG. 5 which comprises a plurality of protrusions with voids 22 disposed therebetween. The voids may be filled with air or an inert gas. Alternatively another material may be provided in the voids in order to tune the diffraction grating according to a particular use. The effectiveness of the grating will depend on the difference in refractive index of the voids and the protrusions as well as the size of the protrusions and voids relative to the wavelength of emitted light.

It will be clear from the arrangement illustrated in FIG. 5 that the cavity filling material 20 does not necessarily fill areas around the side of the electroluminescent device structure within the recess formed by the encapsulant although this may be the case in accordance with certain embodiments. It will also be understood that in accordance with certain embodiments, further layers may be provided. For example, a thin layer encapsulant could be provided between the top electrode 6 and the cavity filling material 20. Furthermore, charge injection and/or transport layers may be provided between the light-emissive layer 8 and the electrodes 4, 6. The light-emissive layer 8 may comprise an array of light-emissive pixels to form a light-emissive display.

FIG. 6 shows a top-emitting organic light emitting device in accordance with another embodiment of the present invention in which the cavity filling material comprises a bulk material 20 and a coating material 24. The coating material may be selected to coat the optical structure and tune its performance. For example, the coating material may be selected according to its refractive index in order to provide a large difference in refractive index between the protrusions and voids 22 in a diffraction grating as illustrated in FIG. 6 thus increasing the effectiveness of the grating. A suitable material for the coating is, for example, SiN although a range of possible materials could be used.

A getter material for absorption of any atmospheric moisture and/or oxygen that may permeate through the substrate or encapsulant may be disposed between the substrate and the encapsulant.

The electrode layers and organic light emitting layer may be deposited by vapour deposition or may be solution processed by, for example, spin coating or inkjet deposition.

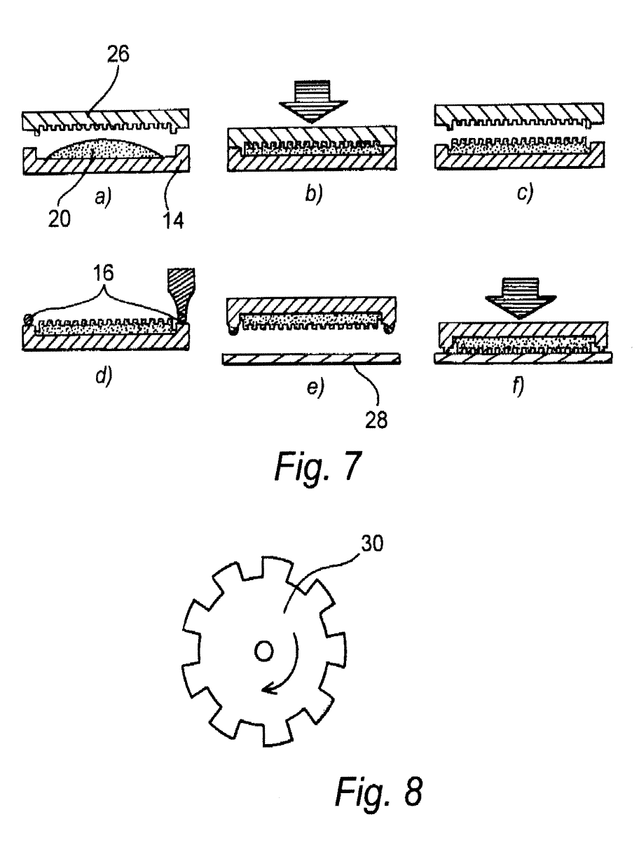

FIG. 7 shows a method of forming a top-emitting organic light emitting device in accordance with an embodiment of the present invention. The method steps may be summarized as follows:

A quantity of (for example) PDMS 20 is dispensed into an etched recess in the encapsulation glass 14.

The PDMS 20 is stamped with a grating profile master 26 which contacts the edge of the encapsulation glass 14 in order to accurately define the height of the grating profile.

After the PDMS 20 is cured the stamp 26 is removed.

Edge-seal glue 16 is dispensed around the edge of the encapsulation glass 14.

The encapsulation glass 14 is then aligned over the top-emitting organic light-emissive display device 28 to be encapsulated

The display device 28 and encapsulation glass 14 are brought together and the glue seal cured. The PDMS profile is in contact with the display device, with a small degree of compression.

Using the process outlined above (or a variation of it) a grating structure is formed on a top emitting device, without processing steps being required on the organic light-emissive display device itself. The PDMS (or similar) material also works to fill the recess in the glass, thereby making the device more robust, and removing Fresnel reflections (which can cause ghosting) from the inside of the glass encapsulant.

The profile of the grating can be precisely referenced to the edge of the encapsulant. For example it might be the case that a grating is to be designed which should provide a nominal 5% compression of the PDMS. If the glue seal thickness is 50 μm and the depth of the etched recess is 200 μm, then the grating will be formed 63 μm above the edge of the encapsulation glass ((200+50)/(200+63)=0.95). The specific design can take into account all design tolerances to ensure a well defined range of compression.

In accordance with another embodiment of the present invention a roller may be used to emboss the optical structure. FIG. 8 shows the structure of a roller 30 which may be used in accordance with this alternative method. The roller 30 comprises a patterned surface for forming the optical structure by rolling over the cavity filling material.

The optical structures can be formed by temporarily softening the cavity filling material (commonly using heat or a solvent) and then embossing the cavity filling material with a master mould. Alternatively, the optical structures can be embossed in the cavity filling material prior to curing.

In order to ensure a clean release of the embossing mould/stamp during the embossing step a release layer may be provided. An example of such a layer is a fluorinated layer such as CF₄ plasma.

Further features of organic electroluminescent devices according to embodiments of the present invention and their method of manufacture are discussed below.

### General Device Architecture

The architecture of the electroluminescent device according to embodiments of the invention comprises a glass or plastic substrate, an anode and a cathode. An electroluminescent layer is provided between the anode and the cathode.

In embodiments of the invention, at least the top electrode is transparent in order that light may be absorbed (in the case of a photoresponsive device) or emitted (in the case of an emissive device).

### Charge Transport Layers

Further layers may be located between the anode and the cathode, such as charge transporting, charge injecting or charge blocking layers.

In particular, it is desirable to provide a conductive hole injection layer, which may be formed from a conductive organic or inorganic material provided between the anode and the electroluminescent layer to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between the anode and the electroluminescent layer preferably has a HOMO level of less than or equal to 5.5 eV, more preferably around 4.8-5.5 eV. HOMO levels may be measured by cyclic voltammetry, for example.

If present, an electron transporting layer located between electroluminescent layer and the cathode preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in the electroluminescent layer include small molecule, polymeric and dendrimeric materials, and compositions thereof. Suitable electroluminescent polymers for use in the electroluminescent layer include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in the electroluminescent layer include electroluminescent metal complexes bearing dendrimeric groups as disclosed in, for example, WO 02/066552.

### Cathode

The cathode is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

If the cathode is the top electrode then in accordance with the present invention it is transparent. Transparent cathodes are particularly advantageous for active matrix devices because emission through a transparent anode in such devices is at least partially blocked by drive circuitry located underneath the emissive pixels. A transparent cathode will comprise a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Optical devices tend to be sensitive to moisture and oxygen. Accordingly, the substrate preferably has good barrier properties for prevention of ingress of moisture and oxygen into the device. The substrate is commonly glass. However, alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is encapsulated with an encapsulant to prevent ingress of moisture and oxygen. A getter material for absorption of any atmospheric moisture and/or oxygen that may permeate through the substrate or encapsulant may be disposed between the substrate and the encapsulant.

### Other

In the previously described embodiments, the device is formed by firstly forming an anode on a substrate followed by deposition of an electroluminescent layer and a cathode. However, it will be appreciated that the device of the invention could also be formed by firstly forming a cathode on a substrate followed by deposition of an electroluminescent layer and an anode.

### Solution Processing

A single polymer or a plurality of polymers may be deposited from solution to form the organic layer(s) of the device. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

While this invention has been particularly shown and described with reference to preferred embodiments thereof, it will be understood by those skilled in the art that various changes in form and details may be made therein without departing from the scope of the invention as defined by the appended claims.

### EXAMPLES

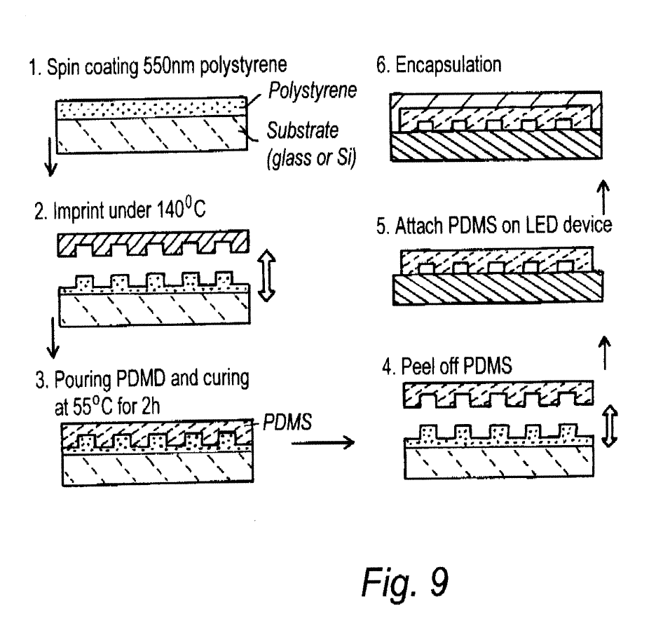

FIG. 9 illustrates an example of a fabrication process in accordance with an embodiment of the present invention. The fabrication process comprises the following steps:
1. Spin coating 550 nm of polystyrene onto a glass or Si substrate.
2. Imprinting the polystyrene with an Si-stamp under 140° C. heat.
3. Pouring PDMD and curing at 55° C. for 2 hours.
4. Peel off the PDMS.
5. Attaching the PDMS on an OLED device.
6. Encapsulation.

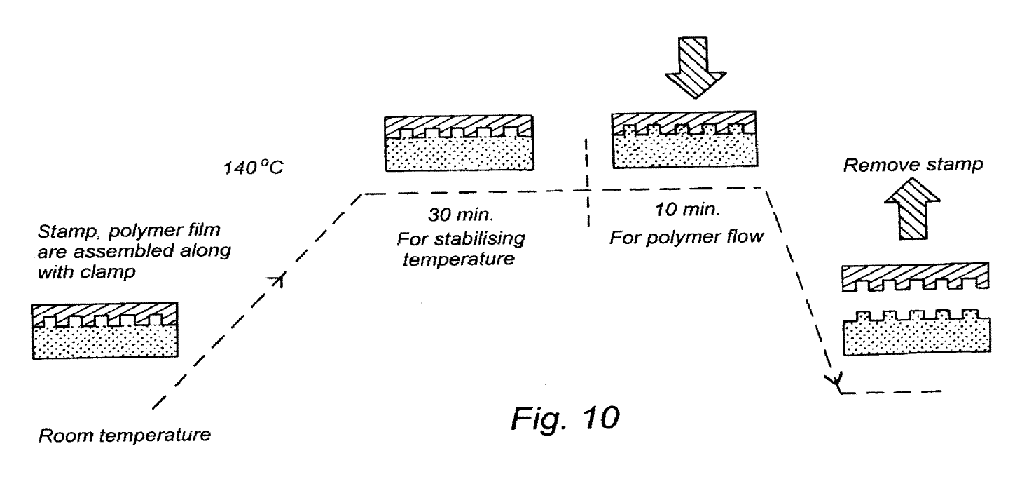

FIG. 10 shows the steps involved in the imprinting step in which the stamp and polystyrene film are assembled and clamped, heated to 140° C., held at 140° C. for the temperature to stabilize and for a further 10 minutes to allow for polymer flow, cooled, and then the stamp is removed.

A number of OLED devices were manufactured, some with a PDMS grating and some without a PDMS grating for comparison. The external quantum efficiency of the OLED devices was measured and it was found that on average the devices including a PDMS grating had an external quantum efficiency 37% higher than the devices without the PDMS grating.

1. An organic electroluminescent device comprising:
a substrate;
a first electrode disposed over the substrate for injecting charge of a first polarity;
a second electrode disposed over the first electrode for injecting charge of a second polarity opposite to said first polarity;
an organic light emitting layer disposed between the first electrode and the second electrode, the second electrode being transparent to light emitted by the light emitting layer;
a glass or transparent plastic encapsulant disposed over and spaced from the second electrode and defining a cavity therebetween; and
a cavity filling material disposed within the cavity, the cavity filling material extending from a bottom side of the cavity to a top side of the cavity, the cavity filling material having an optical structure disposed therein.

2. An organic electroluminescent device according to claim 1, wherein the optical structure is selected from the group consisting of a corrugated surface, a diffractive structure, a microlens array, a prismatic array, and an array of Fresnel lenses.

3. An organic electroluminescent device according to claim 2, wherein the optical structure is a diffraction grating.

4. An organic electroluminescent device according to claim 1, wherein the optical structure is formed in the cavity filling material on an opposite side to the glass or plastic encapsulant.

5. An organic electroluminescent device according to claim 1, wherein the cavity filling material comprises an elastomer.

6. An organic electroluminescent device according to claim 5, wherein the elastomer is polymethylsiloxane.

7. An organic electroluminescent device according to claim 1, wherein the cavity filling material comprises a bulk material in which the optical structure is disposed and a coating material.

8. An organic electroluminescent device according to claim 7, wherein the coating material coats structural elements of the optical structure.

9. An organic electroluminescent device according to claim 7, wherein the coating material is an inorganic material.

10. An organic electroluminescent device according to claim 7, wherein the bulk material is an elastomer.

11. An organic electroluminescent device according to claim 1, wherein the glass or transparent plastic encapsulant comprises a recess in which the cavity filling material is disposed.

12. An organic electroluminescent device according to claim 1, wherein the substrate, the first electrode, the second electrode, the cavity filling material and the encapsulant are all transparent to light emitted by the organic light emitting layer whereby a fully transparent device architecture is provided.

13. A method of manufacturing an organic electroluminescent device comprising the steps:
depositing a first electrode over a substrate for injecting a charge of a first polarity;
depositing an organic light emitting layer over the first electrode;
depositing a second electrode over the organic light emitting layer for injecting charge of a second polarity opposite to said first polarity, the second electrode being transparent to light emitted by the light emitting layer;
disposing a glass or transparent plastic encapsulant over and spaced from the second electrode and defining a cavity therebetween, wherein a cavity filling material is provided within the cavity, the cavity filling material extending from a bottom side of the cavity to a top side of the cavity, the cavity filling material having an optical structure disposed therein.

14. A method according to claim 13, comprising depositing the cavity filling material on the glass or transparent plastic encapsulant prior to disposing the glass or transparent plastic encapsulant over the second electrode.

15. A method according to claim 14, comprising forming the optical structure in the cavity filling material after depositing the cavity filling material on the glass or transparent plastic encapsulant.

16. A method according to claim 13, wherein the optical structure is provided by embossing, printing, etching, or photolithographic patterning.
